(19) United States
(12) Patent Application Publication
(10) Pub. No.: US 2005/0174738 A1
(43) Pub. Date: Aug. 11, 2005

(54) METHOD AND STRUCTURE FOR HEAT SINK ATTACHMENT IN SEMICONDUCTOR DEVICE PACKAGING

(75) Inventors: Roger Lam, Fishkill, NY (US); Wai Mon Ma, Poughkeepsie, NY (US); Vincent L. Montalbano, Hopewell Junction, NY (US); Arch Nuttall, Hyde Park, NY (US); Nandu N. Ranadive, Wappingers Falls, NY (US)

Correspondence Address: CANTOR COLBURN LLP, 55 GRIFFIN ROAD SOUTH, BLOOMFIELD, CT, 06002, US

(73) Assignee: INTERNATIONAL BUSINESS MACHINES CORPORATION, ARMONK, NY (US)

(21) Appl. No.: 10/708,066

(22) Filed: Feb. 6, 2004

(51) Int. Cl. H05K 7/20

(52) U.S. Cl. 361/704

(57) ABSTRACT

A heat sink attachment structure includes an integrated circuit chip mounted on a substrate surface, and a thermal interface layer in contact with the integrated circuit chip. A heat sink is in contact with the thermal interface layer, and at least one spacer member is in contact between the substrate surface and the heat sink, wherein the at least one spacer member is provided with an adhesive material on top and bottom surfaces thereof.

### BACKGROUND OF INVENTION

The present invention relates generally to semiconductor device packaging and, more particularly, to a method and structure for heat sink attachment to a semiconductor chip or package.

The removal of heat from electronic components is a problem continuously faced by electronic packaging engineers. As electronic components have become smaller and more densely packed on integrated boards and chips, designers and manufacturers are now faced with the continuing challenge of how to dissipate the heat generated by these components. It is well known that many electronic components, especially semiconductor components such as transistors and microprocessors, are more prone to failure or malfunction at high temperatures. Thus, the ability to dissipate heat often is a limiting factor on the performance of the component.

Electronic components within integrated circuits have been traditionally cooled via forced or natural convective circulation of air within the housing of the device. In this regard, cooling fins have been provided as an integral part of the component package, or as separately attached elements thereto for increasing the surface area of the package exposed to convectively developed air currents. Electric fans have also been employed to increase the volumetric flow rate of air circulated within the housing. For high power circuits (as well as smaller, more densely packed circuits of presently existing designs), however, simple air circulation often has been found to be insufficient to adequately cool the circuit components.

It is also well known that heat dissipation, beyond that which is attainable by simple air circulation, may be effected by the direct mounting of the electronic component to a thermal dissipation member such as a “cold-plate” or other heat sink apparatus. The heat sink may be a dedicated, thermally conductive metal plate, or simply the chassis of the device. However, the thermal interface surfaces of an electronic component and associated heat sink are typically irregular, either on a gross or a microscopic scale. When these interfaces surfaces are mated, pockets or void spaces are developed therebetween in which air may become entrapped. These pockets reduce the overall surface area contact within the interface that, in turn, reduces the efficiency of the heat transfer therethough. Moreover, as is also well known, air is a relatively poor thermal conductor. Thus, the presence of air pockets within the interface reduces the rate of thermal transfer through the interface.

To improve the efficiency of the heat transfer through the interface, a layer of thermally conductive material is typically interposed between the heat sink and electronic component to fill in any surface irregularities and eliminate/reduce air pockets. Initially employed for this purpose were materials such as silicone grease, or wax filled with a thermally conductive filler such as aluminum oxide. Such materials usually are semi-liquid or solid at normal room temperature, but may liquefy or become fluidic at elevated temperatures to better conform to the irregularities of the interface surfaces.

On the other hand, the greases and waxes generally are not self-supporting or otherwise form stable at room temperature and are considered to be messy to apply to the interface surface of the heat sink or electronic component. To a large extent, elastomeric and phase change materials (PCM) have replaced mica pads and thermal greases as a means for enhancing the heat transfer across a material junction/joint. Elastomeric gaskets of high thermal conductivity are often used as interface materials between the electronic component and the heat spreader or heat sink. However, when solid interstitial materials are used, such as thermal compounds, elastomers or adhesive tapes, the joint conductance problem becomes much more complicated since these materials introduce an additional interface to the problem.

Thus, it is difficult proposition to ensure a consistent thermal interface thickness between a circuit chip and a heat sink. Other approaches have also employed an elaborate alignment/loading fixture to hold the heat sink in place, as well as to hold any thermal interface material to a desired thickness. Furthermore, an adhesive material (such as epoxy) is also typically applied to directly bond a heat sink to a chip, or to bond a thermal interface pad to the heat sink and chip. However, once a bonded heat sink is removed from the chip, the module is no longer useable. Accordingly, it would be desirable to implement a heat sink attachment that eliminates the need for adhesive materials directly on the heat sink and/or chip, and that also provides sufficient thermal conductivity without the need for expensive mechanical retaining hardware.

### SUMMARY OF INVENTION

The foregoing discussed drawbacks and deficiencies of the prior art are overcome or alleviated by a heat sink attachment structure. In an exemplary embodiment, the structure includes an integrated circuit chip mounted on a substrate surface, and a thermal interface layer in contact with the integrated circuit chip. A heat sink is in contact with the thermal interface layer, and at least one spacer member is in contact between the substrate surface and the heat sink, wherein the at least one spacer member is provided with an adhesive material on top and bottom surfaces thereof.

In another embodiment, a method for implementing attachment of a heat sink to and integrated circuit chip includes applying a thermal interface layer to the chip, and adhesively applying a first side of at least one spacer member to a substrate to which the chip is mounted. The heat sink is aligned to the chip, and a load is applied to the heat sink until the heat sink is adhesively bonded to a second side of the at least one spacer member.

In still another embodiment, a semiconductor device packaging assembly includes a chip module mounted on a circuit board substrate, and at least one integrated circuit chip mounted on the chip module. A thermal interface layer is in contact with the at least one integrated circuit chip, and a heat sink is in contact with the thermal interface layer. At least one spacer member is in contact between the chip module and the heat sink, wherein the at least one spacer member is provided with an adhesive material on top and bottom surfaces thereof.

### BRIEF DESCRIPTION OF DRAWINGS

Referring to the exemplary drawings wherein like elements are numbered alike in the several Figures:

FIG. 1 is a side elevation view of a conventional semiconductor device packaging assembly, in which adhesive material is directly applied to an integrated circuit chip;

FIG. 2 is a side elevation view of a semiconductor device packaging assembly, in accordance with an embodiment of the invention, utilizing a plurality of spacer members having adhesive on top and bottom surfaces thereof;

FIG. 3 is a top view of the packaging assembly of FIG. 2, with the heat sink removed; and

FIG. 4 is a flow diagram illustrating a method for implementing heat sink attachment to a semiconductor chip or package, in accordance with another embodiment of the invention.

### DETAILED DESCRIPTION

Disclosed herein is a method and structure for heat sink attachment to a semiconductor chip or package in which an adhesive-free thermal interface layer has a fixed and uniform thickness (e.g., with a thickness tolerance of about ±0.001 inches). Briefly stated, a plurality of spacer members are provided with adhesive on both ends thereof, and are bonded to a module or substrate at one end, and to a heat sink at the other end. In this manner, the thermal interface itself is no longer needed to provide the adhesion for bonding. By separating the adhesion function and the thermal interface function into different components, an improvement in both is attained.

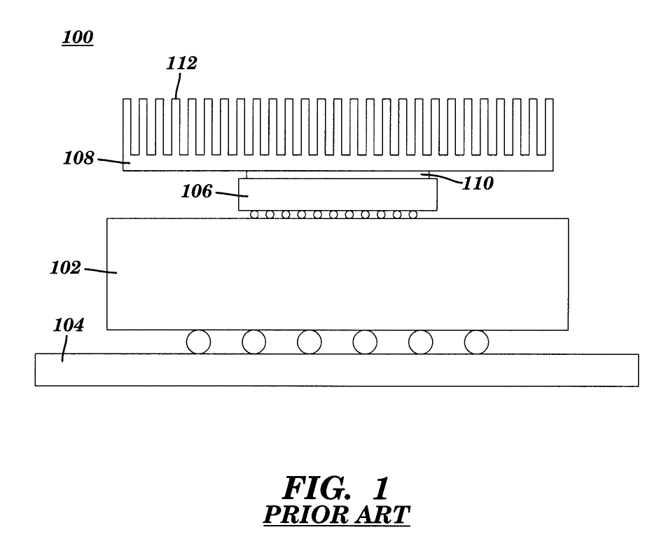

Referring initially to FIG. 1, there is shown a side elevation view of a conventional semiconductor device packaging assembly 100, in which adhesive material is directly applied to an integrated circuit chip. As is shown, assembly 100 generally includes a module 102 attached to a substrate 104, such as a circuit board. The module 102, which may be a multichip module (MCM), for example, has one or more individual semiconductor chips 106 attached thereto. During operation of the individual semiconductor devices formed within the IC chip 106, electrical power is dissipated, transforming electrical energy into heat energy. For high-performance devices, such as microprocessors, specified performance is only achieved when the temperature of the device is below a specified maximum operating temperature. Operation of the device above the maximum operating temperature range, or above the maximum operating temperature, can result in irreversible damage to the device. Moreover, it has been established that the reliability of a semiconductor device decreases with increasing operating temperature.

The heat energy produced by a semiconductor device, such as chip 106, must thus be removed to the ambient environment at a rate that ensures the operation and reliability requirements are met. One conventional approach to facilitating such heat transfer and removal is to directly secure a heat sink 108 to the chip 106 through a thermal interface layer 110 (e.g., a thermally conductive elastomer, such as a thermal interface tape or a thermal interface pad). In the example illustrated, layer 110 is a thermal interface pad made from a homogeneous, epoxy-like material that provides bonding to the chip and heat sink surfaces, as well as fair thermal conduction (e.g., about 1.5 Watts/m-° K.). Alternatively, layer 110 could also be a thermal tape, which is a highly thermally conductive tape (e.g., about 6 Watts/m-° K.) that is sandwiched between thin layers of adhesive on both surfaces. However, the adhesion from this type of configuration is not as effective as that provided by a thermal interface pad, and the adhesive itself reduces the effective thermal conduction.

In either instance, the heat collected and spread through the thermal interface layer 110 is dissipated by means of the heat sink 108, and particularly through individual cooling fins 112 on the heat sink 108 that are exposed to the ambient. Although not shown in FIG. 1, the heat sink 108 may also be mechanically loaded or secured to the thermal interface layer 110 through other conventional means, such as by screws or clamps. As stated previously, a significant disadvantage to the packaging approach illustrated in FIG. 1 is the fact that if it becomes necessary to remove the bonded heat sink 108 is removed from the chip 106, the module 102 would no longer be useable.

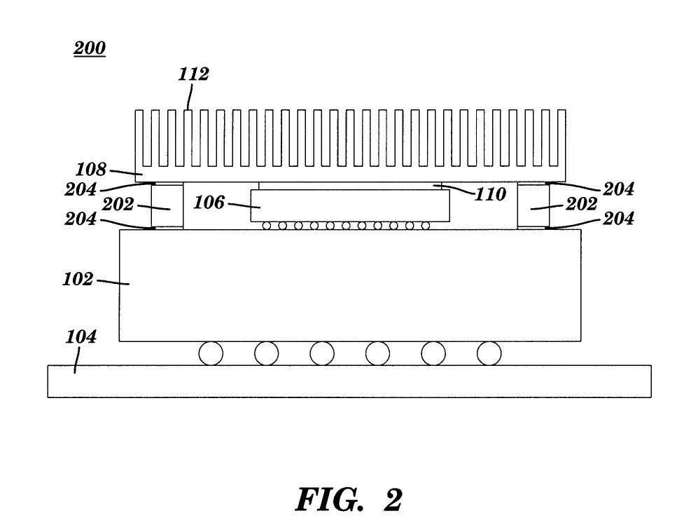

Accordingly, FIG. 2 is a side elevation view of a semiconductor device packaging assembly 200, in accordance with an embodiment of the invention. Instead of integrating an adhesive/bonding function with the thermal interface material itself, a plurality of spacer members 202 are used to accommodate an adhesive material 204 thereon. In this manner, the thermal interface layer 110 need not be selected so as to include adhesive characteristics itself, thereby allowing the layer 110 to have increased thermal conductivity with respect to an adhesive-type thermal interface layer. One suitable material for the thermal interface layer 110 is the THERMFLOW® T776 phase change thermal interface pad manufactured by Chromerics, Inc. A suitable example for the adhesive material 204 is a VHB™acrylate pressure sensitive adhesive, available from 3M Corporation.

In the exemplary embodiment depicted, the spacer members 202 are made from a rigid material having a high tensile strength, such as phenolic. Phenolic is a hard, dense plastic-like material formed by applying heat and pressure to layers of paper or glass cloth impregnated with synthetic resin. These layers or laminations are typically formed from cellulose paper, cotton fabrics, synthetic yarn fabrics, glass fabrics, unwoven fabrics, or the like. When heat and pressure are applied to the layers, a chemical reaction (polymerization) transforms the layers into a high-pressure thermosetting industrial laminated plastic. Other rigid materials, however, may also be used for the spacer members 202.

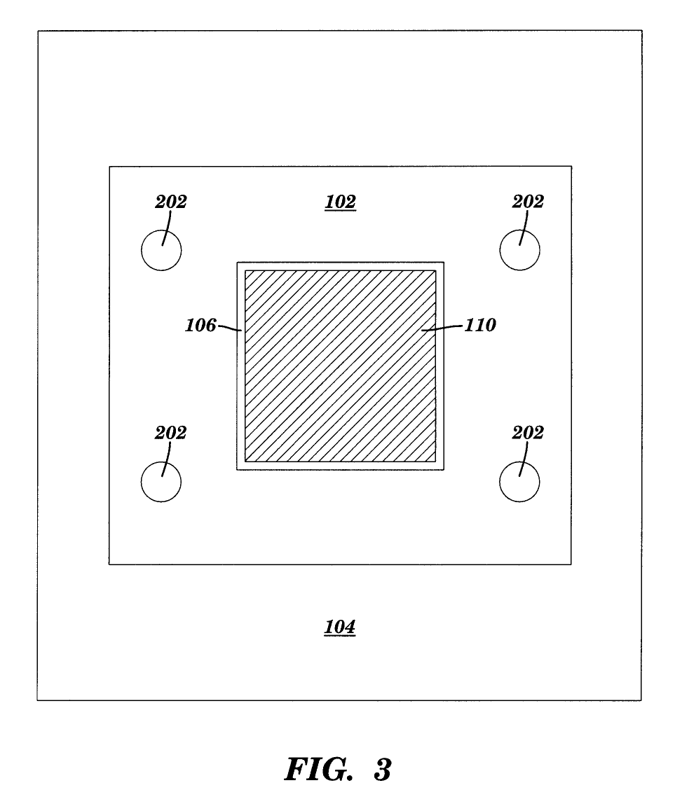

As shown in the top view of FIG. 3, the plurality of spacer members 202 are disposed generally proximate the four corners of the chip 106 and thermal interface layer 110 (although this arrangement may be shifted in any desired pattern with respect to the perimeter of the chip 106). However, additional spacer members may also be used if desired for increased mounting stability of the heat sink. Moreover, if the module 102 is a multichip module, then each chip would preferable include a suitable number of spacer members 202 disposed around each such chip. While a fewer number of spacer members than shown in FIGS. 2 and 3 could be used, it is preferred that a sufficient number be used for desired mechanical stability of the package.

The spacer members 202 may be formed into a generally cylindrical shape, as shown in the Figures. However, other shapes (e.g., cubic) are also contemplated. In addition, while the spacer members 202 are depicted as being formed in a solid configuration, they may also be formed with a cavity therein (i.e., hollowed out). It will be appreciated, however, that any such alternative configurations should also provide sufficient surface area upon which to apply adhesive for bonding to the heat sink and module surfaces.

The adhesive material 204 applied to the spacer members 202 need not have high thermal conductance properties, since the adhesive-free thermal interface layer 110 will preferably be selected for very low thermal impedance. In addition, the adhesive material 204 may be an easily reworkable epoxy (and, for example, curable at room temperature) that has significantly improved bonding strength with respect to any adhesive directly applied to a thermal interface layer, or with respect to a thermal interface layer having an adhesive component thereto. As such, the spacer members allow the use of any thermally conductive material (preferably, but not necessarily, electrically insulating as well), without the need for bonding of the same. In the event that it is desired to remove the bonded heat sink 108, then the spacer members 202 may be cut with a sharp cutting tool. The adhesive material 204 may then be removed from the heat sink 108 and the module 102 with, for example, 3M Citrus Base Industrial Cleaner.

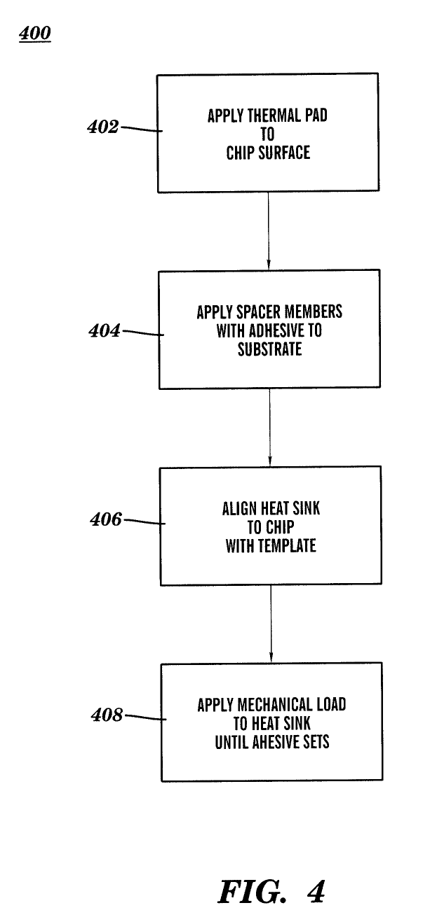

Finally, FIG. 4 is a flow diagram 400 illustrating an exemplary method for implementing heat sink attachment to a semiconductor chip or package, in accordance with a further embodiment of the invention. In block 402, a thermal interface layer, such a thermal interface pad, is applied to the chip surface. For example, a thermal interface pad having a starting thickness of about 6 mils may be used, and later compressed to a thickness of about 4 mils after subsequent attachment of the heat sink. Then, in block 404, the spacer members (with adhesive thereon) are applied to the substrate on which the chip is attached. The thickness or height of the spacer members is selected so as to accommodate the thickness of the bonded chip, as well as the thickness of the thermal interface layer. The adhesive applied to the top and bottom surfaces of the spacer members may have a thickness of about 1 mil, for example. Upon application of the spacer members to the substrate, the heat sink is aligned to the chip through an appropriate template, as shown in block 406. Then, as shown in block 408, a mechanical load is applied to the heat sink until the adhesive on the spacer member has had time to set. Thereafter, any such mechanical loading may be removed.

As will be appreciated, the above described method and structure for heat sink attachment is advantageous in that the need for a thermal interface epoxy is eliminated and, as such, removal of the heat sink will not damage the chip or the module. The separation of the adhesive function from the thermal interface layer to the spacer members allows for higher thermal conductivity of the layer and, accordingly, more consistent thermal energy transfer and dissipation. From a mechanical standpoint, expensive hardware components for loading, heat sink retention and strain relief becomes unnecessary, and the formation of mounting holes in the substrate or printed circuit board are not needed for such heat sink retention hardware.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. A heat sink attachment structure, comprising:
an integrated circuit chip mounted on a substrate surface;
a thermal interface layer in contact with said integrated circuit chip;
a heat sink in contact with said thermal interface layer; and
at least one spacer member in contact between said substrate surface and said heat sink, wherein said at least one spacer member is provided with an adhesive material on top and bottom surfaces thereof.

2. The structure of claim 1, wherein said at least one spacer member comprises a rigid material.

3. The structure of claim 2, wherein said at least one spacer member comprises phenolic.

4. The structure of claim 1, wherein said thermal interface layer is adhesive free.

5. The structure of claim 1, wherein said adhesive material provided on said at least one spacer member comprises a reworkable epoxy curable at room temperature.

6. The structure of claim 1, wherein said thermal interface layer further comprises a thermal interface pad.

7. The structure of claim 6, wherein said thermal interface pad has an initial thickness of about 6 mil and a compressed thickness of about 4 mils.

8. A method for implementing attachment of a heat sink to and integrated circuit chip, the method comprising:
applying a thermal interface layer to the chip;
adhesively applying a first side of at least one spacer member to a substrate to which the chip is mounted;
aligning the heat sink to the chip; and
applying a load to the heat sink until the heat sink is adhesively bonded to a second side of said at least one spacer member.

9. The method of claim 8, wherein said at least one spacer member comprises a rigid material.

10. The method of claim 9, wherein said at least one spacer member comprises phenolic.

11. The method of claim 8, wherein said thermal interface layer is adhesive free.

12. The method of claim 8, wherein said adhesive material provided on said at least one spacer member comprises a reworkable epoxy curable at room temperature.

13. The method of claim 8, wherein said thermal interface layer further comprises a thermal interface pad having an initial thickness of about 6 mil and a compressed thickness of about 4 mils.

14. A semiconductor device packaging assembly, comprising:
a chip module mounted on a circuit board substrate;
at least one integrated circuit chip mounted on said chip module;
a thermal interface layer in contact with said at least one integrated circuit chip;
a heat sink in contact with said thermal interface layer; and
at least one spacer member in contact between said chip module and said heat sink, wherein said at least one spacer member is provided with an adhesive material on top and bottom surfaces thereof.

15. The semiconductor device packaging assembly of claim 14, wherein said at least one spacer member comprises a rigid material.

16. The semiconductor device packaging assembly of claim 15, wherein said at least one spacer member comprises phenolic.

17. The semiconductor device packaging assembly of claim 14, wherein said thermal interface layer is adhesive free.

18. The semiconductor device packaging assembly of claim 14, wherein said adhesive material provided on said at least one spacer member comprises a reworkable epoxy curable at room temperature.

19. The semiconductor device packaging assembly of claim 14, wherein said thermal interface layer further comprises a thermal interface pad.

20. The semiconductor device packaging assembly of claim 19, wherein said thermal interface pad has an initial thickness of about 6 mil and a compressed thickness of about 4 mils.
